(19) United States
(12) Patent Application Publication
(10) Pub. No.: US 2019/0379130 A1
(43) Pub. Date: Dec. 12, 2019

(54) ANTENNA DEVICE USED TO PERFORM DYNAMIC CONTROL FOR FEEDING POINTS AND RADIO FREQUENCY CHAIN CIRCUIT

(71) Applicant: MEDIATEK INC., Hsin-Chu (TW)

(72) Inventors: Ting-Wei Kang, Hsin-Chu (TW); Jenwei Ko, San Jose, CA (US); Yeh-Chun Kao, Hsin-Chu (TW); Chung-Hsin Chiang, Hsin-Chu (TW)

(21) Appl. No.: 16/427,245

(22) Filed: May 30, 2019

Related U.S. Application Data
(60) Provisional application No. 62/681,152, filed on Jun. 6, 2018.

(51) Int. Cl. H01Q 21/00; H04B 1/40; H03F 3/68; H03F 3/20

(52) U.S. Cl. CPC H01Q 21/0006; H04B 1/40; H01Q 25/00; H03F 3/20; H03F 3/68

(57) ABSTRACT

An antenna device may include a first antenna, a second antenna, a switch unit and a radio frequency chain circuit. The first antenna may be used to wirelessly transceive a first signal, and include a first feeding point used to transceive the first signal through a conductive path. The second antenna may be used to wirelessly transceive a second signal, and include a second feeding point used to transceive the second signal through a conductive path. The switch unit may be coupled among the first feeding point, the second feeding point and the radio frequency chain circuit and be used to selectively transceive one of the first signal and the second signal. The radio frequency chain circuit may be used to transceive and process the signal transceived by the switch unit. A nearest gap between the first antenna and the second antenna may be less than 30 millimeters.

### CROSS REFERENCE TO RELATED APPLICATIONS

This application claims priority to provisional Patent Application No. 62/681,152, filed Jun. 6, 2018, and incorporated herein by reference in its entirety.

### BACKGROUND

In the field of antenna application, a commonly used structure is to couple a frequency radio (RF) chain circuit to an antenna, and the RF chain circuit can transceive and process the signal transceived by the antenna. For example, when the antenna transceives signals bi-directionally, the RF chain circuit may receive a signal received by the antenna and transmit another signal to the antenna for the antenna to wirelessly transmit. For example, an RF chain circuit mentioned above may include a set of amplifier(s) to process the signals transceived by the RF chain circuit. Although this type of structure is feasible, some shortcomings are still observed. For example, according to prior art, each antenna has to be coupled to a corresponding RF chain circuit, the quantity of RF chain circuits is difficult to be decreased, and a total size of a whole system is also difficult to be reduced. In addition, this may make related device such as a silicon die or packaged chip more costly. Hence, a solution for this problem is required in the field.

### SUMMARY

An embodiment provides an antenna device including a first antenna, a second antenna, a switch unit, and a radio frequency chain circuit. The first antenna may be used to wirelessly transceive a first signal, and include a first feeding point used to transceive the first signal through a conductive path. The second antenna may be used to wirelessly transceive a second signal, and include a second feeding point used to transceive the second signal through a conductive path. The switch unit maybe coupled among the first feeding point, the second feeding point and the radio frequency chain circuit and be used to selectively transceive one of the first signal and the second signal. The radio frequency chain circuit may be used to transceive and process the one of the first signal and the second signal transceived by the switch unit. The radio frequency chain circuit may include a power amplifier and a low noise amplifier. A nearest gap between the first antenna and the second antenna may be less than 30 millimeters (mm).

Another embodiment provides an antenna including X antennas, Y switch units and Y radio frequency chain circuits. Each of the X antennas may be used to wirelessly transceive a signal, and include at least a feeding point used to optionally transceive the signal through a conductive path. Each of the Y switch units may be coupled among a corresponding radio frequency chain circuit of W radio frequency chains and a corresponding set of K feeding points of the X antennas and be used to selectively transceive one of Z signals where the Z signals are transceived by the X antennas. Each of the Y radio frequency chain circuits may be coupled to a corresponding switch unit of the Y switch units and be used to transceive and process one corresponding signal transceived by the corresponding switch unit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates an antenna device according to an embodiment.

FIG. 2 illustrates antenna radiation patterns of the first antenna and the second antenna of FIG. 1 on a radiation pattern plot according to an embodiment.

FIG. 3 illustrates a top view of the first antenna and the second antenna of FIG. 1 according to another embodiment.

FIG. 4 illustrates a block diagram of the antenna device of FIG. 1 according to an embodiment.

FIG. 5 illustrates a block diagram of the antenna device of FIG. 1 according to another embodiment.

FIG. 6 illustrates an antenna device according to an embodiment.

FIG. 7 illustrates an antenna device according to an embodiment.

FIG. 8 illustrates an example of applying an antenna device according to an embodiment.

### DETAILED DESCRIPTION

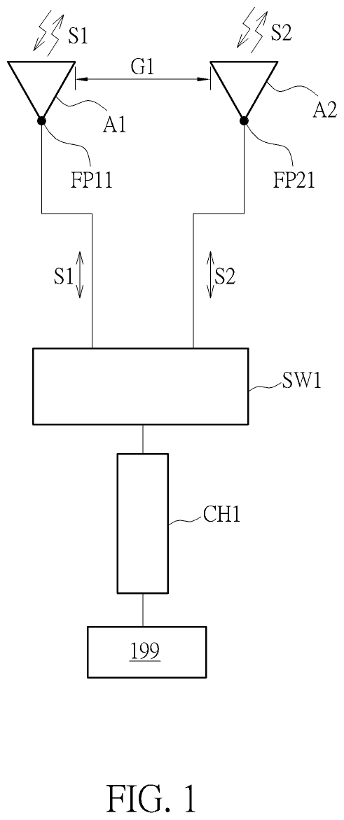

FIG. 1 illustrates an antenna device 100 according to an embodiment. The antenna device 100 may include a first antenna A1, a second antenna A2, a switch unit SW1, a radio frequency (RF) chain circuit CH1. The first antenna A1 maybe used to wirelessly transceive a first signal S1, and include a first feeding point FP11 used to transceive the first signal S1 through a conductive path. The second antenna A2 may be used to wirelessly transceive a second signal S2, and include a second feeding point used to transceive the second signal through a conductive path. The switch unit SW1 may be coupled among the first feeding point FP11, the second feeding point FP21 and the RF chain circuit CH1 and used to selectively transceive one of the first signal S1 and the second signal S2. The RF chain circuit CH1 may be used to transceive and process the one of the first signal S1 and the second signal S2 transceived by the switch unit SW1. According to an embodiment, the RF chain circuit CH1 may be further coupled to a processing circuit 199 for processing a signal transceived by the RF chain circuit CH1.

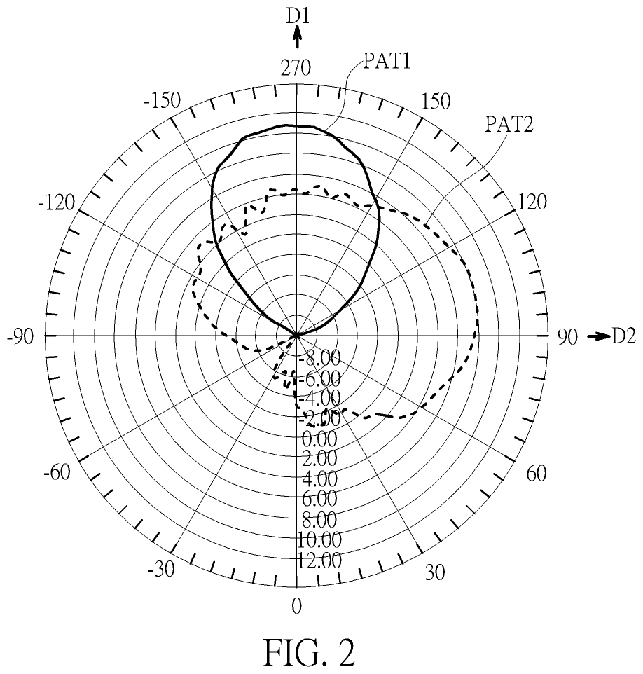

FIG. 2 illustrates antenna radiation patterns of the first antenna A1 and the second antenna A2 of FIG. 1 on a radiation pattern plot according to an embodiment. FIG. 2 merely provides an example instead of limiting the scope of embodiment. According to an embodiment, as shown in FIG. 2, the first antenna A1 may have a first radiation pattern PAT1, the second antenna A2 may have a second radiation pattern PAT2, and the first radiation pattern PAT1 may be different from the second radiation pattern PAT2. As shown in FIG. 2, according to an embodiment, the first antenna A1 may have a first peak gain direction D1, the second antenna A2 may have a second peak gain direction D2, and the first peak gain direction D1 may be different from the second peak gain direction D2.

Regarding the antenna device 100 of FIG. 1, according to an embodiment, the first antenna A1 may be a broadside antenna, and the second antenna A2 may be an end-fire antenna. According to another embodiment, the first antenna A1 may be a front-side antenna, and the second antenna A2 may be a back-side antenna.

According to another embodiment, the first antenna A1 may be a first end-fire antenna with a first peak gain direction on an antenna pattern plot, the second antenna A2 may be a second end-fire antenna with a second peak gain direction on the antenna pattern plot, and the first peak gain direction may be different from the second peak gain direction.

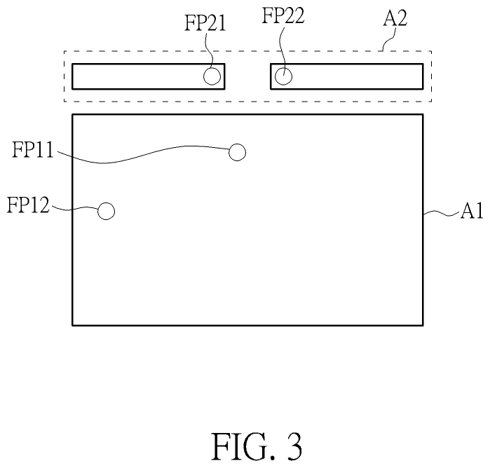

FIG. 3 illustrates a top view of the first antenna A1 and the second antenna A2 of FIG. 1 according to another embodiment. In the example of FIG. 3, the first antenna A1 may be a broadside antenna, and the second antenna A2 maybe a dipole antenna. As shown in FIG. 3, each of the first antenna A1 and the second antenna A2 may further include at least another feeding point. For example, as shown in FIG. 3, the first antenna A1 may further include another feeding point FP12 in addition to the first feeding point FP11 described in FIG. 1. According to an embodiment, the first feeding point (e.g., FP11) and another feeding point (e.g., FP12) of the first antenna A1 may be used to excite the first antenna A1 in the same polarization direction. In other words, an antenna including a plurality of feeding points may be compatible and feasible with the antenna device 100 of FIG. 1.

Likewise, according to embodiments, the second antenna A2 may include merely one feeding point (e.g., the feeding point FP21 in FIG. 1 and FIG. 3) or a plurality of feeding points (e.g., the feeding point F21 and another feeding point FP22 in FIG. 3).

According to an embodiment, each of the first antenna A1 and the second antenna A2 may be a differential antenna when the antenna has two feeding points and signals fed in the two feeding points are in antiphase.

According to an embodiment, the first antenna A1 of FIG. 1 may be a differential broadside antenna. For example, the first antenna A1 of FIG. 1 may be a differential patch antenna according to an embodiment.

According to an embodiment, the first antenna A1 of FIG. 1 may be a differential end-fire antenna. For example, the first antenna A1 of FIG. 1 may be a differential dipole antenna according to an embodiment.

In FIG. 3, the first antenna A1 merely includes two feeding points, that is, the feeding points FP11 and FP12. However, FIG. 3 merely provides an example instead of limiting the number of the feeding point (s) of an antenna. According to an embodiment, the first antenna A1 of FIG. 1 may further include n other feeding points where n is a positive integer and n>0 . However, the allowed number of feeding point(s) of an antenna may be determined according to performance of power and signal transceiving of the antenna. In this case, the first feeding point FP11 and the n other feeding points of the first antenna A1 may be used to excite the first antenna A1 in the same polarization direction.

According to an embodiment, in FIG. 1, the first antenna A1 and/or the second antenna A2 may be used to operate at a frequency not lower than 7.125 Gigahertz (GHz). Hence, for example, the antenna device 100 may be feasible for applications of 5G (5th Generation) communications.

According to an embodiment, a nearest gap G1 between the first antenna A1 and the second antenna A2 may be less than 30 millimeters (mm). According to another embodiment, the gap G1 may be determined according to frequency of the signal S1 and/or the signal S2. Hence, according to an embodiment, the antenna device 100 may be feasible when the first antenna A1 and the second antenna A2 are substantially close to one another, and the first antenna A1 and the second antenna A2 are not transceiving signals concurrently. According to an embodiment, a radio frequency chain circuit may include at least a power amplifier and a low noise amplifier as described below.

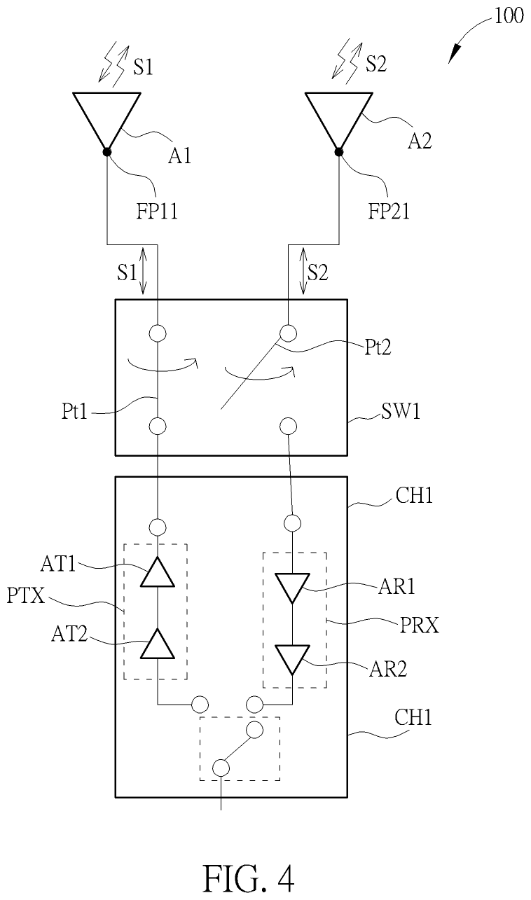

FIG. 4 illustrates a block diagram of the antenna device 100 of FIG. 1 according to an embodiment. As shown in FIG. 4 and FIG. 1, the RF chain unit CH1 may include a transmission path unit PTX used to send a signal to at least one of the first antenna A1 and the second antenna A2, and a reception path unit PRX used to receive another signal from at least one of the first antenna A1 and the second antenna A2. The switch unit SW1 may include a first conductive path Pt1 and a second conductive path Pt2. The first conductive path Pt1 may be optionally coupled between the first feeding point FP11 and one of the transmission path unit PTX and the reception path unit PRX. The second conductive path Pt2 may be optionally coupled between the second feeding point FP21 and one of the transmission path unit PTX and the reception path unit PRX. According to an embodiment, when the first conductive path Pt1 is coupled between the first feeding point FP11 and one of the transmission path unit PTX and the reception path unit PRX, the second conductive path Pt2 is not concurrently coupled between the second feeding point FP21 and one of the transmission path unit and the reception path unit. In other words, when one of the first feeding point FP11 and the second feeding point FP21 is coupled to one of the transmission path unit PTX and the reception path unit PRX, the other one of the first feeding point FP11 and the second feeding point FP21 is not coupled to any of the transmission path unit PTX and the reception path unit PRX. Hence, the antennas A1 and A2 are not expected to operate simultaneously. The switch unit SW1 in FIG. 4 may be similar to a double pole double throw (DPDT) switch unit.

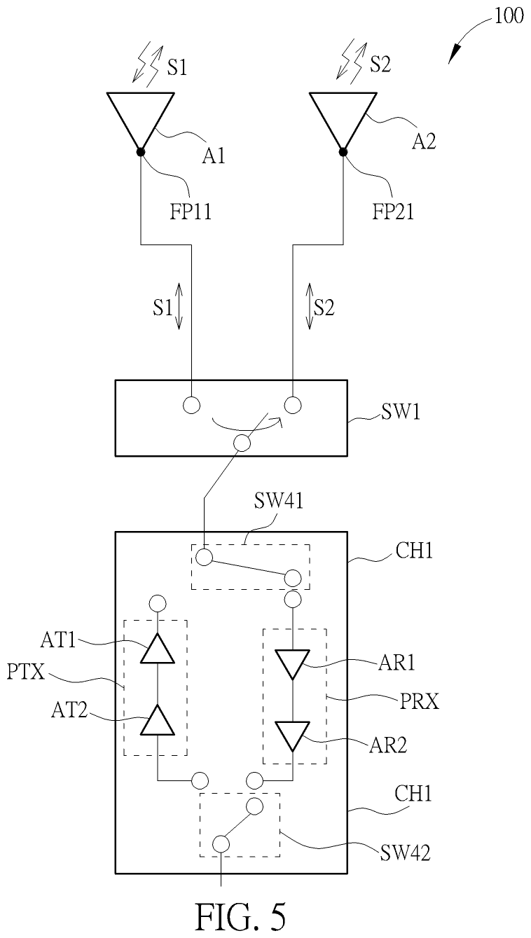

FIG. 5 illustrates a block diagram of the antenna device 100 of FIG. 1 according to another embodiment. As shown in FIG. 5, the switch unit SW1 may include a first terminal selectively coupled to the first feeding point FP11 or the second feeding point FP21 for transceiving one of the first signal S1 and the second signal S2, and a second terminal. The radio frequency chain circuit CH1 may include a first terminal coupled to the second terminal of the switch unit SW1, and a second terminal. The RF chain circuit CH1 may include a transmission path unit PTX, a reception path unit PRX, a switch SW41 and a switch SW42. When the RF chain circuit CH1 is used to receive a signal from an antenna, the switches SW41 and SW42 maybe coupled to the reception path unit PRX. When the RF chain circuit CH1 is used to transmit a signal to an antenna, the switches SW41 and SW42 may be coupled to the transmission path unit PTX. The switch unit SW1 and the switches SW41 and SW42 may be similar to single pole double throw (SPDT) switches.

As shown in FIG. 4 and FIG. 5, the transmission path unit PTX may include a set of amplifier(s) such as amplifiers AT1 and AT2. For example, the amplifiers AT1 and AT2 maybe coupled in series where an output terminal of the amplifier AT2 may be coupled to an input terminal of the amplifier AT1. As shown in FIG. 4, the reception path unit PRX may include a set of amplifier(s) such as amplifiers AR1 and AR2. For example, the amplifiers AR1 and AR2 may be coupled in series where an output terminal of the amplifier AR1 may be coupled to an input terminal of the amplifier AR2. According to an embodiment, the RF chain circuit CH1 may include a power amplifier (a.k.a. PA) and a low noise amplifier (a.k.a. LNA). For example, the amplifier AT1 may be a power amplifier, the amplifier AR1 may be a low noise amplifier, and each of the amplifiers AT2 and AR2 may be a variable gain amplifier (a.k.a. VGA). FIG. 4 merely provides an example of a block diagram of the RF chain circuit CH1 instead of limiting the scope of embodiments. According to another embodiment, the RF chain circuit CH1 may further include a phase shifter for adjusting a phase of a signal transceived by the RF chain circuit CH1.

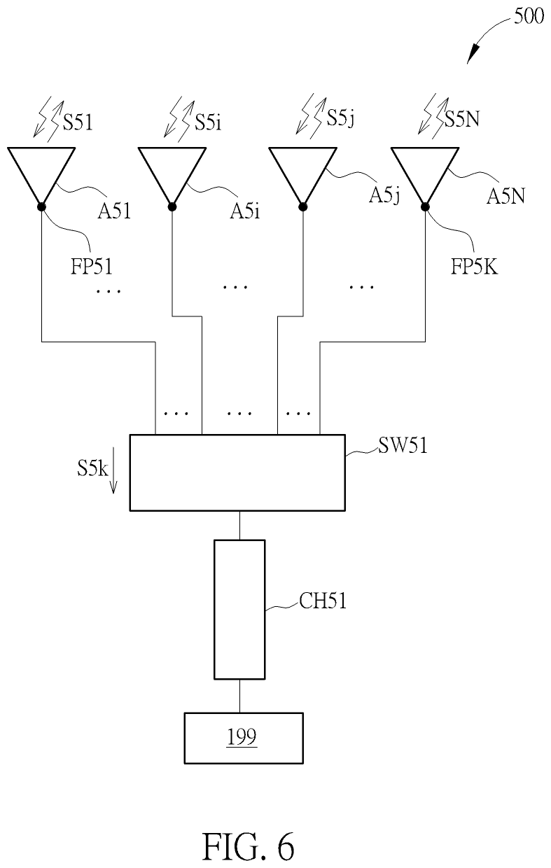

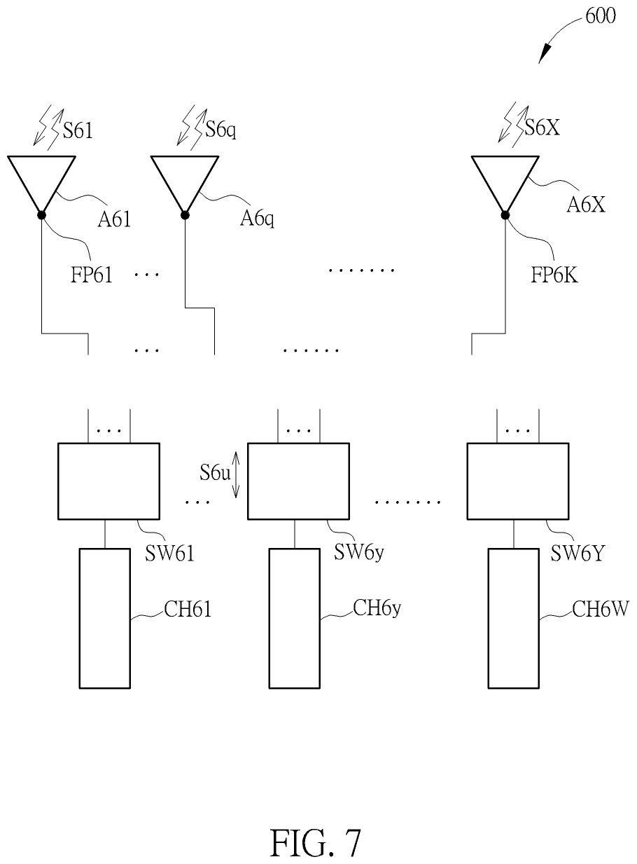

FIG. 1, FIG. 4 and FIG. 5 merely provide examples instead of limiting scope of embodiments. According to an embodiment, the switch unit SW1 and the RF chain circuit CH1 in FIG. 1, FIG. 4 and FIG. 5 may be integrated as a circuit or a block. For example, when designing an integrated circuit (IC), the switch unit SW1 and the RF chain circuit CH1 may be integrated as a block. Likewise, in FIG. 6 and FIG. 7, a set of switch unit(s) and a set of RF chain circuit(s) may be integrated as a block.

In FIG. 4 and FIG. 5, each of the transmission path unit PTX and the reception path unit PRX may have two stages of amplifiers. However, FIG. 4 and FIG. 5 may be merely examples and schematic diagrams. The number of stage of amplifiers may be not limited by examples of FIG. 4 and FIG. 5. Each of the transmission path unit PTX and the reception path unit PRX may include more elements in addition to the amplifiers shown in FIG. 4 and FIG. 5.

FIG. 6 illustrates an antenna device 500 according to an embodiment. The antenna device 500 may include N antennas A51 to A5N, a switch unit SW51 and an RF chain circuit CH51. N may be a positive integer larger than 1. Each of the N antennas A51 to A5N may be used to wirelessly transceive a signal, and include at least a feeding point used to optionally transceive the signal through a conductive path. For example, an i^{th} antenna A5i of the antennas A51 to A5N may be used to wirelessly transceive a signal S5i, and include at least one feeding point used to optionally transceive the signal S5i through a conductive path. The switch unit SW51 may be selectively coupled among K feeding points FP51 to FP5K of the N antennas A51 to A5N and a RF channel circuit CH51. The switch unit SW51 may be used to transceive one of M signals where the M signals are transceived by the N antennas A51 to A5N. In FIG. 6, the first antenna A51 may transceive a signal S51, the N^{th} antenna A5N may transceive a signal S5N, and so on, so there maybe N signals S51 to S5N in FIG. 6. However, the number of signals transceived by the N antennas A51 to A5N may be M, and M may be smaller than N because a part of the antennas A51 to A5N may not transceive signal(s). For example, as shown in FIG. 6, a signal S5k may be transceived by the switch unit SW51. The RF chain circuit CH51 may be used to transceive and process the one of M signals transceived by the switch unit SW51 (e.g., the signal S5k). According to an embodiment, the structure of the RF chain circuit CH51 may be similar to the RF chain circuit CH1 of FIG. 1, FIG. 4 and FIG. 5, so it is not repeatedly described. N, i, M, K and k may be positive integers, 1<N, 1≤i≤N, 1<M≤N, N≤K and 1≤k≤M. In FIG. 6 and FIG. 7, dots may indicate portion(s) that is/are not illustrated.

According to an embodiment, regarding FIG. 6, the i^{th} antenna A5i of the N antennas A51 to A5N may have an i^{th} radiation pattern on a radiation pattern plot, a j^{th} antenna A5j of the N antennas A51 to A5N may have a j^{th} radiation pattern on the radiation pattern plot, and the i^{th} radiation pattern may be different from the j^{th} radiation pattern. i and j are positive integers, and 1≤i<j≤N.

According to an embodiment, each of the N antennas A51 to A5N may include one or more feeding point(s). The N antennas A51 to A5N may include K feeding points, K is a positive integer, N>K, and 8≤K. In other words, the number of the feeding points in FIG. 6 may be not less than eight according to an embodiment.

FIG. 7 illustrates an antenna device 600 according to an embodiment. The antenna device 600 may include X antennas A61 to A6X, Y switch units SW61 to SW6Y and W RF chain circuits CH61 to CH6W. Each of the X antennas A61 to A6X may be used to wirelessly transceive a signal and include at least a feeding point used to optionally transceive the signal through a conductive path. For example, a q^{th} antenna A6q of the antennas A61 to A6X may be used to wirelessly transceive a signal S6q, and include at least a feeding point used to optionally transceive the signal S6q through a conductive path. Each of the Y switch units SW61 to SW6Y may be selectively coupled among a corresponding RF chain circuit of the W RF chain circuits CH61 to CH6W and a corresponding set of K feeding points FP61-FP6K of the X antennas. Each of the Y switch units SW61 to SW6Y may be used to selectively transceive one of Z signals where the Z signals are transceived by the X antennas A61 to A6X. In FIG. 7, the first antenna A61 may transceive a first signal S61, an Xth antenna A6X may transceive an Xth signal S6X, and so on, so there may be X signals S61 to S6X in FIG. 7. However, the number of signals transceived by the X antenna A61 to A6X may be Z, and Z may be smaller than X because a part of the antennas A61 to A6X may not transceive signal (s). For example, a switch unit SW6y of the Y switch units SW61 to SW6Y may be used to transceive a signal S6u of the Z signals transceived by the X antennas A61 to A6X. Each of the W RF chain circuits CH61 to CH6W may be coupled to a corresponding switch unit of the Y switch units SW61 to SW6Y and used to transceive and process one corresponding signal transceived by the corresponding switch unit. According to an embodiment, a number of signals transceived by antennas (e.g., Z described above) may be less than or equal to a number of feeding points (e.g., K described above) , and a number of RF chain circuits (e.g., Y described above) may be less than or equal to a number of feeding points (e.g., K). X, Y, Z, q, y, u, W and K may be positive integers, 1<X, 1≤q≤X, 1<Y≤K, 1<Z≤K, 1≤W, X≤K and 1≤u≤Z.

As shown in FIG. 7, a plurality of feeding points (i.e., two or more feeding points) respectively belonging to different antennas may be arranged to one switch unit, the switch unit may be selectively coupled to one selected feeding point, and a corresponding RF chain circuit may transceive and process signals of the selected feeding point.

As described above, in FIG. 7, the number Y may be smaller than the number X, and the number of the RF chain circuits CH61 to CH6W may be smaller than the number of the antennas A61 to A6X.

According to an embodiment, each of the X antennas A61 to A6X may have one or more feeding point(s). Hence, according to an embodiment, the X antennas A61 to A6X may include the K feeding points FP61 to FP6K. K may be a positive integer, and K>W. In other words, the number of feeding points FP61 to FP6K of the antennas A61 to A6X may be larger than the number of the RF chain circuits CH61 to CH6W.

According to another embodiment, Y<K and 8≤K. In other words, the number of feeding points (e.g., K in FIG. 7) of the antennas A61 to A6X may be larger than the number of the RF chain circuits CH61 to CH6W, and the number of the RF chain circuits CH61 to CH6W may be at least 8.

According to an embodiment, in FIG. 7, a set of antennas of the antennas A61 to A6X may be integrated to be a communication unit. According to an embodiment, the set of antennas integrated as a communication unit may not operate simultaneously.

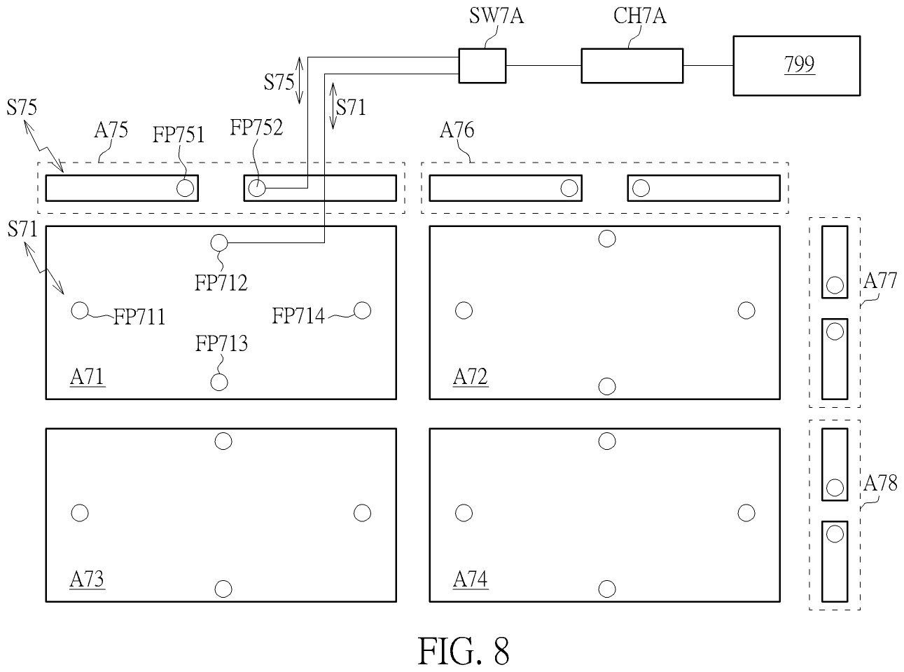

FIG. 8 illustrates an example of applying an antenna device according to an embodiment. As shown in FIG. 8, four broadside antennas A71 to A74 and four end-fire antennas A75 to A78 may be disposed together. For example, the antennas A71 to A74 maybe patch antennas, and the antennas A75 to A78 may be dipole antennas. In the example of FIG. 8, each of the antennas A71 to A74 may have four feeding points, and each of the antennas A75 to A78 may have two feeding points. For example, the antenna A71 may be used to transceive a signal S71 and have four feeding points FP711 to FP714, and the antenna A75 may be used to transceive a signal S75 and have two feeding points FP751 and FP752. For example, if the antennas A71 and A75 are expected not to operate simultaneously, the antennas A71 and A75 are allowed to share the same RF chain circuit, the feeding points FP712 and FP752 may be coupled to a switch unit SW7A. The switch unit SW7A may be selectively coupled to one of the feeding points FP712 and FP752 for an RF chain circuit CH7A to transceive and process the selected one of the signals S71 and S75. The signal transceived by the RF chain circuit CH7A may be transceived to/from a processing circuit 799. In FIG. 8, the switch unit SW7A and the RF chain circuit CH7A may be similar to the switch unit SW1 of FIG. 1 and the RF chain circuit CH1 of FIG. 4 and FIG. 5 described above, so it is not repeatedly described.

In summary, by means of an antenna device with a switch unit provided by an embodiment, a plurality of feeding points of different antennas may be selectively coupled to an RF chain circuit to be processed and transceived by the RF chain circuit. An antenna device of an embodiment may be used to perform dynamic management and controls for a plurality of feeding points and an RF chain circuit. Hence, the number of RF chain circuits may be effectively reduced, and related cost and circuit/chip size may be reduced. According to embodiments, a used switch unit (e.g. , each of SW1, SW51 and SW61 to SW6Y described above) is a switchable device instead of a power divider or a hybrid coupler, so power corresponding to a transceived signal may not be reduced, and quality of the signal may not be deteriorated. As compared with a conventional device, by means of an antenna device provided by an embodiment, substantially same performance may be achieved using fewer RF chain circuits, and improved performance may be achieved without increasing the number of RF chain circuits. Hence, an antenna device provided by an embodiment is helpful to deal with problems in the field.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An antenna device comprising:
a first antenna configured to wirelessly transceive a first signal, and comprising a first feeding point configured to transceive the first signal through a conductive path;
a second antenna configured to wirelessly transceive a second signal, and comprising a second feeding point configured to transceive the second signal through a conductive path;
a switch unit coupled among the first feeding point, the second feeding point and a radio frequency chain circuit and configured to selectively transceive one of the first signal and the second signal; and
the radio frequency chain circuit configured to transceive and process the one of the first signal and the second signal transceived by the switch unit;
wherein the radio frequency chain circuit comprises a power amplifier and a low noise amplifier, and a nearest gap between the first antenna and the second antenna is less than 30 millimeters (mm).

2. The antenna device of claim 1, wherein:
the radio frequency chain unit comprises a transmission path unit configured to send a signal to at least one of the first antenna and the second antenna, and a reception path unit configured to receive another signal from at least one of the first antenna and the second antenna;
the switch unit comprises:
a first conductive path optionally coupled between the first feeding point and one of the transmission path unit and the reception path unit; and
a second conductive path optionally coupled between the second feeding point and one of the transmission path unit and the reception path unit;
wherein when the first conductive path is coupled between the first feeding point and one of the transmission path unit and the reception path unit, the second conductive path is not concurrently coupled between the second feeding point and one of the transmission path unit and the reception path unit.

3. The antenna device of claim 1, wherein:
the switch unit comprises a first terminal selectively coupled to the first feeding point or the second feeding point for transceiving one of the first signal and the second signal, and a second terminal; and
the radio frequency chain circuit comprises a first terminal coupled to the second terminal of the switch unit, and a second terminal.

4. The antenna device of claim 1, wherein the first antenna has a first radiation pattern, the second antenna has a second radiation pattern, and the first radiation pattern is different from the second radiation pattern.

5. The antenna device of claim 1, wherein the first antenna has a first peak gain direction, the second antenna has a second peak gain direction, and the first peak gain direction is different from the second peak gain direction.

6. The antenna device of claim 1, wherein the first antenna is a broadside antenna, and the second antenna is an end-fire antenna.

7. The antenna device of claim 1, wherein the first antenna is a front-side antenna, and the second antenna is a back-side antenna.

8. The antenna device of claim 1, wherein the first antenna is a first end-fire antenna with a first peak gain direction, the second antenna is a second end-fire antenna with a second peak gain direction, and the first peak gain direction is different from the second peak gain direction.

9. The antenna device of claim 1, wherein the first antenna further comprises another feeding point.

10. The antenna device of claim 9, wherein the first feeding point and the another feeding point of the first antenna are configured to excite the first antenna in a same polarization direction.

11. The antenna device of claim 9, wherein the first antenna is a differential antenna.

12. The antenna device of claim 11, wherein the first antenna is a differential broadside antenna.

13. The antenna device of claim 12, wherein the first antenna is a differential patch antenna.

14. The antenna device of claim 11, wherein the first antenna is a differential end-fire antenna.

15. The antenna device of claim 14, wherein the first antenna is a differential dipole antenna.

16. The antenna device of claim 1, wherein the first antenna further comprises n other feeding points wherein n is a positive integer and n>0.

17. The antenna device of claim 16, wherein the first feeding point and the n other feeding points of the first antenna are configured to excite the first antenna in a same polarization direction.

18. The antenna device of claim 1, wherein the first antenna and/or the second antenna is configured to operate at a frequency not lower than 7.125 Gigahertz (GHz).

19. The antenna device of claim 1, wherein the radio frequency chain circuit further comprises a phase shifter.

20. An antenna device comprising:
X antennas each configured to wirelessly transceive a signal and comprising at least a feeding point configured to optionally transceive the signal through a conductive path;
Y switch units each coupled among a corresponding radio frequency chain circuit of W radio frequency chains and a corresponding set of K feeding points of the X antennas and configured to selectively transceive one of Z signals wherein the Z signals are transceived by the X antennas; and
the W radio frequency chain circuits each coupled to a corresponding switch unit of the Y switch units and configured to transceive and process one corresponding signal transceived by the corresponding switch unit;
wherein X, Y, Z, W and K are positive integers, 1<Z≤K, X≤K, 1≤W and 1≤Y≤K.
